(19) United States
(12) Patent Application Publication
(10) Pub. No.: US 2017/0069700 A1
(43) Pub. Date: Mar. 9, 2017

(54) Display Substrate and Method for Manufacturing the Same, and Display Device

(71) Applicant: BOE Technology Group Co., Ltd., Beijing (CN)

(72) Inventors: Yue HU, Beijing (CN); Ze LIU, Beijing (CN)

(21) Appl. No.: 15/135,234

(22) Filed: Apr. 21, 2016

(30) Foreign Application Priority Data
Sep. 7, 2015 (CN) 201510564816.1

(51) Int. Cl. H01L 27/32; H01L 51/56; H01L 51/52

(52) U.S. Cl. CPC H01L 27/3258; H01L 27/3246; H01L 51/5237; H01L 27/3262; H01L 51/56

(57) ABSTRACT

The present disclosure relates to the field of display technologies and discloses a display substrate and a method for manufacturing the same, and a display device comprising the display substrate. The display substrate includes a planarization layer which is made of a material of organosilicon, and the organosilicon adheres the planarization layer to an organic material film and an inorganic material film. The method for manufacturing the display substrate includes a step of forming a planarization layer, wherein the planarization layer is configured for providing a planar surface; and the step of forming the planarization layer includes: preparing organosilicon which is used for forming the planarization layer; forming an organosilicon film via a film-forming process; and curing the organosilicon film to form the planarization layer.

### CROSS-REFERENCE TO RELATED APPLICATION

This application claims the priority to Chinese Patent Application No. 201510564816.1 filed on Sep 7, 2015, the disclosure of which is incorporated in their entirety by reference herein.

### TECHNICAL FIELD

The present disclosure relates to the field of display technologies, and in particular, to a display substrate and a method for manufacturing the same, and a display device.

### BACKGROUND

At present, in an Active Matrix Organic Light Emitting Diode (AMOLED) display apparatus, the structure of the array substrate thereof is as shown in FIG. 1, wherein 1 is the base substrate of the array substrate, 2 is a gate electrode, 3 is an active layer, 4 is a source electrode, 5 is a drain electrode, 6 is an inorganic insulating layer, 7 is a planarization layer, 8 is a pixel definition layer (PDL), 9 is an anode that includes a transparent conducting material and metal of silver, 10 is a gate insulating layer, 11 is an organic luminescent layer, and 12 is a cathode.

In the prior art, the planarization layer 7 usually employs an organic material, for example, an organic resin. The processing technique for an organic material is simple, and a planar surface may be provided. The inorganic insulating layer 6 usually employs a material of SiOx or SiNx, wherein SiOx or SiNx may generate a hydrogen bond by reacting with an organic material, thus the adsorptivity may be increased. However, the adsorptivity of the organic material and the transparent conducting material is poor, and it tends to cause the planarization layer 7 and the anode 9 to depart from each other.

### SUMMARY

The present disclosure provides a display substrate and a method for manufacturing the same, thereby solving the problem that the adsorptivity of the planarization layer and the transparent conducting layer on a display substrate is poor and it tends to cause the planarization layer and the transparent conducting layer to depart from each other.

The present disclosure further provides a display device, which employs the above display substrate to improve the yield and quality of the products.

In order to solve the above technical problems, one embodiment of the present disclosure provides a display substrate, which includes a planarization layer that is configured for providing a planar surface, wherein the material of the planarization layer includes organosilicon, and the organosilicon adheres the planarization layer to an organic material film and an inorganic material film.

In one example, the display substrate further includes an inorganic insulating layer and a conducting layer, the planarization layer covers the inorganic insulating layer, and the conducting layer is arranged on the planarization layer.

In one example, the material of the inorganic insulating layer includes silicon nitride or silicon oxide.

In one example, the organosilicon is manufactured by dissolving a silicone gel in an aliphatic or aromatic alkane or an aliphatic or aromatic haloalkane.

In one example, the organosilicon is manufactured by a hydrolytic polymerization reaction of tetraethyl orthosilicate and H₂O.

In one example, the display substrate is an active matrix organic light-emitting diode array substrate, which includes:
a base substrate;
a thin-film transistor arranged on the base substrate;
an inorganic insulating layer that covers the thin-film transistor;
a planarization layer that covers the inorganic insulating layer;
a pixel definition layer arranged on the planarization layer, for defining a plurality of pixel regions;
an anode arranged on the planarization layer and located in the pixel region, wherein the anode is electrically connected with a drain electrode of the thin-film transistor by a via hole that penetrates through the planarization layer and the inorganic insulating layer;
an organic luminescent layer arranged on the anode and located in the pixel region; and
a cathode that covers the organic luminescent layer.

One embodiment of the present disclosure further provides a method for manufacturing a display substrate, which includes a step of forming a planarization layer, wherein the planarization layer is configured for providing a planar surface, and the step of forming the planarization layer includes:
preparing organosilicon which is used for forming the planarization layer;
forming an organosilicon film via a film-forming process; and
curing the organosilicon film to form the planarization layer.

In one example, the manufacture method further includes:
forming an inorganic insulating layer before the step of forming the planarization layer.

During the step of forming the planarization layer, the planarization layer is formed on the inorganic insulating layer.

The manufacture method further includes:
forming a conducting layer on the planarization layer after the step of forming the planarization layer.

In one example, the material of the inorganic insulating layer includes silicon nitride or silicon oxide.

In one example, the step of preparing the organosilicon which is used for forming the planarization layer includes:
dissolving a silicone gel in an aliphatic or aromatic alkane or an aliphatic or aromatic haloalkane to obtain the organosilicon.

In one example, the step of forming the organosilicon film via the film-forming process includes:
forming the organosilicon film via a blade-coating film-forming process.

In one example, the step of preparing the organosilicon which is used for forming the planarization layer includes:
forming an organosilicon polymer solution by carrying out a hydrolytic polymerization reaction of tetraethyl orthosilicate and H₂O.

In one example, the step of carrying out a hydrolytic polymerization reaction of tetraethyl orthosilicate and H₂O includes:
dissolving tetraethyl orthosilicate in absolute ethyl alcohol, adding a certain amount of H₂O and glycerol, and obtaining a mixed solution; and
adding a certain amount of concentrated hydrochloric acid into the mixed solution and stirring, thus carrying out a primary hydrolytic polymerization reaction of tetraethyl orthosilicate and H₂O, and when the solution becomes clear and transparent, adding an aqueous solution of polyvinyl alcohol and stirring, thus carrying out a secondary hydrolytic polymerization reaction of tetraethyl orthosilicate and H₂O.

In one example, the step of forming the organosilicon film via the film-forming process includes:
forming the organosilicon film with a certain thickness via a whirl-coating film-forming process, and then subjecting the organosilicon film to heat treatment; and
repeating the above step until a required thickness of the organosilicon film is obtained.

One embodiment of the present disclosure further provides a display device, which includes the above display substrate.

The above technical solutions of the present disclosure have the following beneficial effects.

In the above technical solutions, the planarization layer of the display substrate is made of a material including organosilicon, and because organosilicon has the performance of both an organic material and an inorganic material, the adhesivity of the planarization layer to the organic material film and the inorganic material film can be increased, and the planarization layer may be prevented from departing from the interface with an adjacent film, thereby it may guarantee the performance of the display substrate, and the product quality may be improved.

### BRIEF DESCRIPTION OF THE DRAWINGS

In order to more clearly illustrate the technical solutions of the embodiments of the present disclosure or the prior art, the drawings required in the description of the embodiments or the prior art will be briefly introduced below. Apparently, the drawings in the description below only show some embodiments of the present disclosure, and other drawings may also be obtained by one of ordinary skills in the art based on these drawings without creative work.

FIG. 1 shows a structural representation of an active matrix organic light-emitting diode array substrate in the related art;

FIG. 2 shows a structural representation of an active matrix organic light-emitting diode display panel according to one embodiment of the present disclosure.

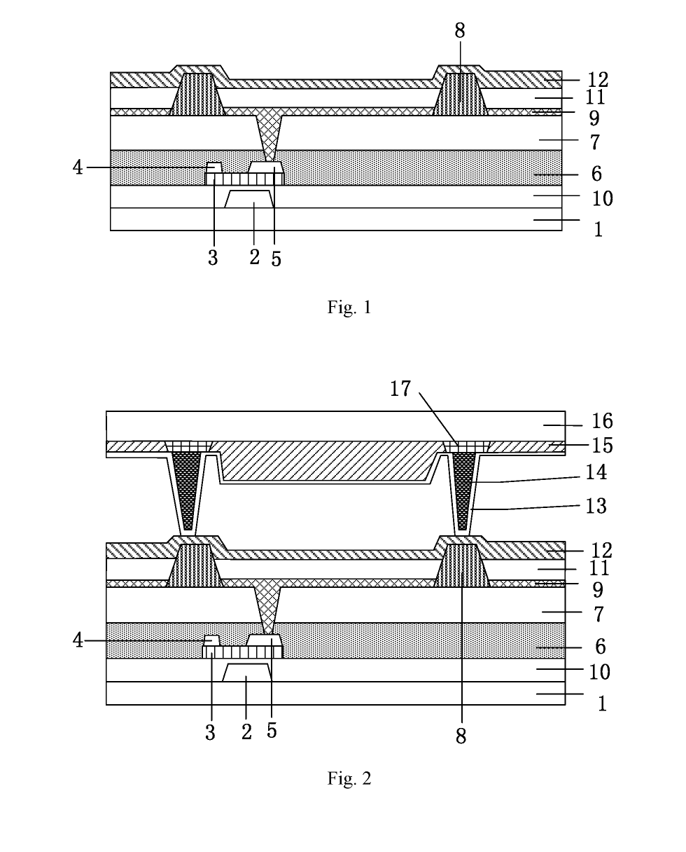

### DETAILED DESCRIPTION

The present disclosure provides a display substrate, which includes a planarization layer for providing a planar surface, the material of the planarization layer includes organosilicon, and because organosilicon has the performance of both an organic material and an inorganic material, the planarization layer has good adhesivity with an organic material film and an inorganic material film, and the planarization layer may be prevented from peeling off from an adjacent film, thereby the performance of the display substrate may be guaranteed, and the product quality may be improved.

Organosilicon is an organosilicon compound, which refers to a compound that contains a Si—C bond and in which at least one organic group is directly connected with a silicon atom. Conventionally, a compound in which an organic group is connected with a silicon atom via oxygen, sulfur, nitrogen and the like is also regarded as an organosilicon compound. Polysiloxanes that take a silicon-oxygen bond (—Si—O—Si—) as the backbone are organosilicon compounds that are most popular, most deeply researched and most widely applied, and occupy over about 90% of the total amount used. Organosilicon materials have a unique structure:
1) Abundant methyls on the Si atom screens the polysiloxane backbone with high-energy;
2) C—H has no polarity, so the intermolecular interaction force is very weak;
3) The length of Si—O bond is long, and the bond angle of the Si—O—Si bond is large; and
4) Si—O bond is a covalent bond that has 50% of the ionic bond characteristics (a covalent bond has directivity, but an ionic bond has no directivity).

Because organosilicon has a unique structure, it has the performances of both an inorganic material and an organic material; it has the basic properties of low surface tension, small viscosity-temperature coefficient, high compressibility and high gas permeability, etc., moreover, it has the excellent features of high-low temperature resistance, electrical insulation, oxidation-resistant stability, weathering resistance, flame resistance, hydrophobicity, corrosion resistance, nontoxicity and smellessness and physiological inertia, etc.

Moreover, organosilicon has a good film-forming feature, thus the film-forming quality of the planarization layer can be guaranteed.

Materials in the prior art that have the performances of both an organic material and an inorganic material are not limited to organosilicon, other materials that are easy for film forming and have the performances of both an organic material and an inorganic material may be readily thought of and selected by one skilled in the art based on the inventive concept of the present disclosure, for replacing organosilicon and implementing the technical solutions of the present disclosure, which also pertain to the protection scope of the present disclosure.

The specific implementation of the present disclosure will be further described in detail in conjunction with the drawings and embodiments. The embodiments below are only used for illustrating the present disclosure, rather than limiting the scope of the present disclosure.

Referring to FIG. 2, a display substrate according to one embodiment of the present disclosure includes a plurality of semiconductor elements, for example, a thin-film transistor, and an inorganic insulating layer 6 is covered on the semiconductor element for blocking water and oxygen and protecting the semiconductor performance of the thin-film transistor. In one embodiment, the material of the inorganic insulating layer 6 usually includes SiOx or SiNx. Because SiOx and SiNx can generate a hydrogen bond by reacting with an organic material, the adhesivity may be increased. Therefore, a SiOx or SiNx film also has a good adhesivity with an organic material film.

A planarization layer 7 is covered on the inorganic insulating layer 6 for providing a planar surface. A conducting layer 9 is arranged on the planarization layer 7. The material of the conducting layer 9 includes an inorganic material such as metal, metal alloy or metal oxide, etc.

In one embodiment, the material of the planarization layer 7 is organosilicon. Because organosilicon has the performance of both an organic material and an inorganic material, the planarization layer 7 has good adhesivity with both the inorganic insulating layer 6 and the conducting layer 9, so that the planarization layer 7 may be prevented from peeling off from the inorganic insulating layer 6 and the conducting layer 9, thereby the performance of the display substrate may be guaranteed.

When the inorganic insulating layer 6 is replaced by an organic insulating layer, the planarization layer 7 also has good adhesivity with the organic insulating layer and the conducting layer 9, so that the planarization layer 7 may be prevented from peeling off from the organic insulating layer and the conducting layer 9, thereby the performance of the display substrate may be guaranteed.

In the technical solution of the present disclosure, it is configured that the material of the planarization layer includes organosilicon which has the performance of both an organic material and an inorganic material, so that the planarization layer has good adhesivity with both the organic material film and the inorganic material film, the planarization layer may be prevented from peeling off from an adjacent film, thereby the performance of the display substrate may be guaranteed, and the product quality may be improved.

In one embodiment, the organosilicon may be manufactured by dissolving a silicone gel in an aliphatic or aromatic alkane or an aliphatic or aromatic haloalkane. Or, it may be manufactured by carrying out a hydrolytic polymerization reaction of tetraethyl orthosilicate and H₂O. An exemplary manufacture process will be introduced below. It should be noted that the manufacture method of the organosilicon is not limited to the above two methods, and it will not be listed one by one here.

An active matrix light emitting diode array substrate is taken as an example, and the display substrate according to one embodiment of the present disclosure may include:
a first base substrate 1, which is a transparent base substrate, for example, a glass base substrate, a quartz base substrate or an organic resin base substrate;
a thin-film transistor arranged on the first base substrate 1, and when the thin-film transistor is a bottom gate-type thin-film transistor, it includes a gate electrode 2, a gate insulating layer 10 that covers the gate electrode 2, an active layer 3 arranged on the gate insulating layer 10, and a source electrode 4 and a drain electrode 5 that are lap-jointed on the active layer. The thin-film transistor is not limited to a bottom gate-type thin-film transistor, and it may also be a top gate-type thin-film transistor or a coplane-type thin-film transistor or the like;
an inorganic insulating layer 6 that covers the thin-film transistor, the material of which is silicon nitride or silicon oxide;
a planarization layer 7 that covers the inorganic insulating layer 6;
a pixel definition layer 8 arranged on the planarization layer 7, wherein the pixel definition layer 8 is light-tight, for defining a plurality of pixel regions;
a conducting layer 9 arranged on the planarization layer 7 and located in the pixel region, wherein the conducting layer 9 is the anode of the light emitting diode, and it is electrically connected with the drain electrode 5 of the thin-film transistor by a via hole that penetrates through the planarization layer 7 and the inorganic insulating layer 6. The material of the planarization layer 7 includes organosilicon, which has good adhesivity with both the inorganic insulating layer 6 and the conducting layer 9. In the case of an organic light-emitting diode array substrate with a top emission structure, the conducting layer 9 also functions as a reflecting electrode, and its material includes metal or metal alloy, for example, metal such as Cu, Al, Ag, Mo, Cr, Nd, Ni, Mn, Ti, Ta, W and the like and an alloy of those kinds of metal (for example, Mo—Al—Mo);
an organic luminescent layer 11 arranged on the conducting layer 9 and located in the pixel region;
a cathode 12 that covers the organic luminescent layer 11, wherein a common voltage is applied on the cathode 12, a pixel voltage is transferred to the conducting layer 9 of each pixel region via the thin-film transistor, and the voltage difference between the conducting layer 9 and the cathode 12 controls the organic luminescent layer 11 in the corresponding pixel region to emit light. In the case of an organic light-emitting diode array substrate with a top emission structure, the cathode 12 is transflective, and its material is metal oxide, for example, tin indium oxide or zinc indium oxide.

In the case of an active matrix light emitting diode array substrate, in order to simplify the manufacture process, the organic luminescent layers 11 in all the pixel regions are formed simultaneously via a one-time process, and the organic luminescent layers 11 will emit lights of the same color.

Moreover, in order to realize color display, the active matrix light emitting diode display panel is configured to further include a color filter substrate. As shown in FIG. 2, the color filter substrate includes:
a second base substrate 16, which is a transparent base substrate, for example, a glass base substrate, a quartz base substrate or an organic resin base substrate;
a black matrix 17 arranged on the second base substrate 16, for defining a plurality of pixel regions, wherein positions of the pixel regions on the color filter substrate have a one-to-one correspondence with that of the pixel regions on the array substrate;
a color filter layer 15 arranged on the second base substrate 16 and located in the pixel region, for cooperating with the light emitted by the organic luminescent layer 11, so as to realize color display, for example, when the organic luminescent layer 11 emits a white light, the color filter layer 15 may include, but is not limited to, a red filter layer, a green filter layer and a blue filter layer;
a spacer 14 arranged on the black matrix 17, for supporting the cell thickness of the display panel;
an auxiliary electrode 13 arranged on the spacer 14, which electrically contacts the cathode 12 after the array substrate and the color filter substrate are oppositely arranged to form a cell, so as to apply a common voltage to the cathode 12. The material of the auxiliary electrode 13 may be a transparent metal oxide, for example, tin indium oxide or zinc indium oxide.

The active matrix light emitting diode display panel manufactured according to the technical solution of the present disclosure has the following advantages: because the planarization layer 7 has good adhesivity with both an organic material film and an inorganic material film, the planarization layer 7 will not be peeled off from the inorganic insulating layer 6, so that the inorganic insulating layer 6 can function to resist moisture, filth and other atmosphere constituents. The planarization layer 7 has good adhesivity with the conducting layer 9, thus good electrical performance and long-term stability of the conducting layer 9 can be guaranteed. At the same time, good adhesivity between layers can also alleviate the mechanical stress and tension caused by a mechanical and thermal impact and shock.

One embodiment of the present disclosure further provides a method for manufacturing a display substrate, which includes a step of forming a planarization layer, wherein the planarization layer is configured for providing a planar surface. The above step of forming the planarization layer includes:
preparing an organosilicon which is used for forming the planarization layer;
forming an organosilicon film via a film-forming process;
curing the organosilicon film to form the planarization layer.

In the above step, the organosilicon film may be cured by heating or under normal temperature.

When the display substrate includes a semiconductor element, the manufacture method further includes:
forming an inorganic insulating layer that covers the semiconductor element, wherein the inorganic insulating layer may block water and oxygen and thus protect the semiconductor performance of the above semiconductor element, and the material of the inorganic insulating layer generally includes silicon nitride or silicon oxide;

In the step of forming the planarization layer, the planarization layer is formed on the inorganic insulating layer.

The above manufacture method further includes:
forming a conducting layer on the planarization layer after step of forming the planarization layer, wherein the material of the conducting layer includes metal, metal alloy or metal oxide.

The adjacent films of the planarization layer formed by the above steps include an inorganic insulating layer and a conducting layer, and because the material of the planarization layer, i.e., organosilicon, has the performance of both an organic material and an inorganic material, the planarization layer has good adhesivity with both the inorganic insulating layer and the conducting layer, so that the planarization layer may be prevented from peeling off from the inorganic insulating layer and the conducting layer, thereby the performance of the display substrate may be guaranteed, and the product quality may be improved.

Similarly, when the inorganic insulating layer is replaced by an organic insulating layer, it can also prevent the planarization layer from peeling off from the organic insulating layer and the conducting layer.

The preparation process of the organosilicon is very important. If good film-forming performance of the organosilicon can be guaranteed, the film-forming quality of the planarization layer will be guaranteed.

In one exemplary implementation mode, the organosilicon which is used for forming the planarization layer is manufactured by dissolving a silicone gel in an aliphatic or aromatic alkane or an aliphatic or aromatic haloalkane. Then, the step of preparing the organosilicon includes:
dissolving a silicone gel in an aliphatic or aromatic alkane or an aliphatic or aromatic haloalkane to obtain the organosilicon.

For example, an organosilicon film may be formed via a blade-coating film-forming process.

An exemplary process of the above blade-coating film-forming process may be as follows: the shape of the display substrate is configured as a rectangle, the film-forming equipment has a long strip-shaped nozzle, the nozzle is placed above the long side of the display substrate and is configured to be parallel to the long side of the rectangle, then the nozzle is driven to scan along the broad side of the rectangle at a uniform speed so as to spray the organosilicon on the whole display substrate, thereby an organosilicon film is formed.

In another exemplary implementation mode, the organosilicon which is used for forming the planarization layer is manufactured by carrying out a hydrolytic polymerization reaction of tetraethyl orthosilicate and H₂O. Then, the step of preparing the organosilicon includes:
forming an organosilicon polymer solution by carrying out a hydrolytic polymerization reaction of tetraethyl orthosilicate and H₂O.

For example, an organosilicon film with a certain thickness may be formed via a whirl-coating film-forming process, and then the organosilicon film is subjected to heat treatment. The above step is repeated until a required thickness of the organosilicon film is obtained.

In the above hydrolytic polymerization reaction, the reaction equation of tetraethyl orthosilicate and H₂O is:

nSi(OR)₄+(2n−1.5)H₂O=(RO)₃—Si—O(—Si—O)ₙ₋₂—Si—OH+(4n−3)HOR

For example, the step of carrying out the hydrolytic polymerization reaction of tetraethyl orthosilicate and H₂O includes:
dissolving tetraethyl orthosilicate in absolute ethyl alcohol, and adding a certain amount of H₂O and glycerol (C₃H₅(OH)₃), thus obtaining a mixed solution; and
adding a certain amount of concentrated hydrochloric acid into the mixed solution and stirring, thus carrying out a primary hydrolytic polymerization reaction of tetraethyl orthosilicate and H₂O, and when the solution becomes clear and transparent, adding an aqueous solution of polyvinyl alcohol and stirring, thus carrying out a secondary hydrolytic polymerization reaction of tetraethyl orthosilicate and H₂O.

In one embodiment, during the hydrolytic polymerization reaction of tetraethyl orthosilicate and H₂O, H₂O and tetraethyl orthosilicate are of equal amount of substance. The volume of the aqueous solution of polyvinyl alcohol is 10-15 ml, and the mass percentage of polyvinyl alcohol is about 5%.

In a practical preparation process, the above secondary hydrolytic polymerization reaction is generally performed for 60 min, and then the reaction solution is filtered by slow-speed filter paper, thus an organosilicon polymer solution may be obtained.

After the organosilicon polymer solution is prepared, for example, a film-forming process is carried out of the organosilicon polymer solution via a whirl coater at a speed of 1800-2200 r/min for 20 s-40 s in a super clean room, then a heat treatment is carried out at 340-360° C. for 30-35 min and the heating rate is kept at 2-5° C./min. The above operation is repeated until the organosilicon film reaches the required thickness. Finally, the organosilicon film is subjected to heat treatment at a certain temperature for 30-35 min.

One embodiment of the present disclosure further provides a display device, which includes the display substrate according to the embodiments of the present disclosure. The planarization layer of the above display substrate can have good adhesivity with adjacent organic material film and inorganic material film, and it will not peel off, so that the performance of the display substrate may be guaranteed, and the quality of the display apparatus may be improved.

The display device may include liquid crystal display device, organic light-emitting diode display device, touch display device or other display devices. For example, the display device may include any product or component that has a display function, for example, display panel, electronic paper, OLED panel, mobile phone, tablet computer, TV set, display, notebook computer, digital photo frame and navigator, etc.

The above description only shows some preferred embodiments of the present disclosure. It should be noted that, various improvements and substitutions may also be made by one of ordinary skills in the art without departing from the technical principles of the present disclosure, and all these improvements and substitutions should be regarded as falling into the protection scope of the present disclosure.

What is claimed is:

1. A display substrate, comprising a planarization layer that is configured for providing a planar surface, wherein a material of the planarization layer comprises organosilicon, and the organosilicon adheres the planarization layer to an organic material film and an inorganic material film.

2. The display substrate according to claim 1, wherein the display substrate further comprises an inorganic insulating layer and a conducting layer, the planarization layer covers the inorganic insulating layer, and the conducting layer is arranged on the planarization layer.

3. The display substrate according to claim 2, wherein a material of the inorganic insulating layer comprises silicon nitride or silicon oxide.

4. The display substrate according to claim 1, wherein the organosilicon is manufactured by dissolving a silicone gel in an aliphatic or aromatic alkane or an aliphatic or aromatic haloalkane.

5. The display substrate according to claim 1, wherein the organosilicon is manufactured by a hydrolytic polymerization reaction of tetraethyl orthosilicate and H₂O.

6. The display substrate according to claim 1, wherein the display substrate is an active matrix organic light-emitting diode array substrate which comprises:
a base substrate;
a thin-film transistor provided on the base substrate;
an inorganic insulating layer that covers the thin-film transistor;
the planarization layer that covers the inorganic insulating layer;
a pixel definition layer that is provided on the planarization layer, for defining a plurality of pixel regions;
an anode arranged on the planarization layer and located in the pixel region, wherein the anode is electrically connected with a drain electrode of the thin-film transistor by a via hole that penetrates through the planarization layer and the inorganic insulating layer;
an organic luminescent layer arranged on the anode and located in the pixel region; and
a cathode that covers the organic luminescent layer.

7. The display substrate according to claim 2, wherein the display substrate is an active matrix organic light-emitting diode array substrate which comprises:
a base substrate;
a thin-film transistor provided on the base substrate;
an inorganic insulating layer that covers the thin-film transistor;
a planarization layer that covers the inorganic insulating layer;
a pixel definition layer arranged on the planarization layer, for defining a plurality of pixel regions;
an anode arranged on the planarization layer and located in the pixel region, wherein the anode is electrically connected with a drain electrode of the thin-film transistor by a via hole that penetrates through the planarization layer and the inorganic insulating layer;
an organic luminescent layer arranged on the anode and located in the pixel region; and
a cathode that covers the organic luminescent layer.

8. The display substrate according to claim 3, wherein the display substrate is an active matrix organic light-emitting diode array substrate which comprises:
a base substrate;
a thin-film transistor provided on the base substrate;
an inorganic insulating layer that covers the thin-film transistor;
a planarization layer that covers the inorganic insulating layer;
a pixel definition layer arranged on the planarization layer, for defining a plurality of pixel regions;
an anode arranged on the planarization layer and located in the pixel region, wherein the anode is electrically connected with a drain electrode of the thin-film transistor by a via hole that penetrates through the planarization layer and the inorganic insulating layer;
an organic luminescent layer arranged on the anode and located in the pixel region; and
a cathode that covers the organic luminescent layer.

9. The display substrate according to claim 4, wherein the display substrate is an active matrix organic light-emitting diode array substrate which comprises:
a base substrate;
a thin-film transistor provided on the base substrate;
an inorganic insulating layer that covers the thin-film transistor;
a planarization layer that covers the inorganic insulating layer;
a pixel definition layer arranged on the planarization layer, for defining a plurality of pixel regions;
an anode arranged on the planarization layer and located in the pixel region, wherein the anode is electrically connected with a drain electrode of the thin-film transistor by a via hole that penetrates through the planarization layer and the inorganic insulating layer;
an organic luminescent layer arranged on the anode and located in the pixel region; and
a cathode that covers the organic luminescent layer.

10. The display substrate according to claim 5, wherein the display substrate is an active matrix organic light-emitting diode array substrate which comprises:
a base substrate;
a thin-film transistor provided on the base substrate;
an inorganic insulating layer that covers the thin-film transistor;
a planarization layer that covers the inorganic insulating layer;
a pixel definition layer arranged on the planarization layer, for defining a plurality of pixel regions;
an anode arranged on the planarization layer and located in the pixel region, wherein the anode is electrically connected with a drain electrode of the thin-film transistor by a via hole that penetrates through the planarization layer and the inorganic insulating layer;
an organic luminescent layer arranged on the anode and located in the pixel region; and
a cathode that covers the organic luminescent layer.

11. A method for manufacturing a display substrate, comprising a step of forming a planarization layer, wherein the planarization layer is configured for providing a planar surface, and the step of forming the planarization layer comprises:
preparing organosilicon which is used for forming the planarization layer;
forming an organosilicon film via a film-forming process; and
curing the organosilicon film to form the planarization layer.

12. The manufacture method according to claim 11, further comprising:
forming an inorganic insulating layer before the step of forming the planarization layer;
wherein the planarization layer is formed on the inorganic insulating layer during the step of forming the planarization layer.

13. The manufacture method according to claim 11, further comprising:
forming a conducting layer on the planarization layer after the step of forming the planarization layer.

14. The manufacture method according to claim 12, wherein the material of the inorganic insulating layer comprises silicon nitride or silicon oxide.

15. The manufacture method according to claim 11, wherein the step of preparing the organosilicon which is used for forming the planarization layer comprises:
dissolving a silicone gel in an aliphatic or aromatic alkane or an aliphatic or aromatic haloalkane to obtain the organosilicon.

16. The manufacture method according to claim 15, wherein the step of forming the organosilicon film via the film-forming process comprises:
forming the organosilicon film via a blade-coating film-forming process.

17. The manufacture method according to claim 11, wherein the step of preparing the organosilicon which is used for forming the planarization layer comprises:
forming an organosilicon polymer solution by carrying out a hydrolytic polymerization reaction of tetraethyl orthosilicate and H₂O.

18. The manufacture method according to claim 17, wherein the step of carrying out the hydrolytic polymerization reaction of tetraethyl orthosilicate and H₂O comprises:
dissolving tetraethyl orthosilicate in absolute ethyl alcohol, adding a certain amount of H₂O and glycerol, and obtaining a mixed solution; and
adding a certain amount of concentrated hydrochloric acid into the mixed solution and stirring, thus carrying out a primary hydrolytic polymerization reaction of tetraethyl orthosilicate and H₂O, and when the solution becomes clear and transparent, adding an aqueous solution of polyvinyl alcohol and stirring, thus carrying out a secondary hydrolytic polymerization reaction of tetraethyl orthosilicate and H₂O.

19. The manufacture method according to claim 17, wherein the step of forming the organosilicon film via the film-forming process comprises:
forming the organosilicon film with a certain thickness via a whirl-coating film-forming process, and then subjecting the organosilicon film to heat treatment;
repeating the above step until a required thickness of the organosilicon film is obtained.

20. A display device, comprising the display substrate according to claim 1.
